(19) United States
(12) Patent Application Publication
(10) Pub. No.: US 2021/0288300 A1
(43) Pub. Date: Sep. 16, 2021

(54) METHOD OF MAKING PARTICLES CONTAINING METAL AND ACTIVE BATTERY MATERIAL FOR ELECTRODE FABRICATION

(71) Applicant: Intecells, Inc., Southfield, MI (US)

(72) Inventor: Xiaohong Gayden, West Bloomfield, MI (US)

(73) Assignee: Intecells, Inc., Southfield, MI (US)

(21) Appl. No.: 17/187,058

(22) Filed: Feb. 26, 2021

Related U.S. Application Data
(60) Provisional application No. 62/989,132, filed on Mar. 13, 2020.

(51) Int. Cl. H01M 4/04; H01M 4/587

(52) U.S. Cl. CPC H01M 4/0426; H01M 10/0525; H01M 4/587

(57) ABSTRACT

A method of making an electrode material for a lithium-ion electrochemical cell includes sputtering a wire of metal or metal alloy in an atmospheric plasma to produce activated particles of metal or metal alloy and contacting the activated particles of the metal or metal alloy with particles of a lithium-ion cell active electrode material to produce composite particles in which particles of the first lithium-ion cell active electrode material are adhered to particles of the metal or metal alloy.

### CROSS-REFERENCE TO RELATED APPLICATIONS

This application claims benefit of U.S. Provisional Patent Application No. 62/989,132, filed Mar. 13, 2020, which is hereby incorporated by reference in its entirety.

### TECHNICAL FIELD

This specification relates to methods of making materials for electrodes of lithium-ion cells and to the electrodes and lithium-ion cells and batteries prepared with such materials.

### INTRODUCTION

This section provides information helpful in understanding the invention but that is not necessarily prior art.

Assemblies of lithium-ion battery cells find increasing applications in providing motive power in automotive vehicles. Each lithium-ion cell of the battery may provide an electrical potential of about three to four volts and a direct electrical current, depending on the composition and mass of the electrode materials in the cell. Lithium-ion battery cells can be discharged and re-charged over many cycles. A battery is assembled by combining a suitable number of individual cells in a combination of electrical parallel and series connections to satisfy voltage and current requirements for an electric motor of an electrically powered vehicle. The assembled battery may, for example, have perhaps three hundred individually packaged cells that are electrically interconnected to provide forty to four hundred volts and sufficient electrical power to an electrical traction motor to drive a vehicle.

Each lithium-ion cell typically comprises a negative electrode layer (anode, during cell discharge), a positive electrode layer (cathode, during cell discharge), a thin porous separator layer interposed in face-to-face contact between parallel, facing, electrode layers, a liquid, lithium-containing, electrolyte solution filling the pores of the separator and contacting the facing surfaces of the electrode layers for transport of lithium ions during repeated cell discharging and re-charging cycles, and a thin layer of a metallic current collector. In another arrangement, the positive and negative electrode layers may be separated by a solid polyelectrolyte layer. Because a battery requires such a great number of lithium-ion cells to provide sufficient electrical power to an electrical traction motor to drive a vehicle, an efficient, high quality production method is a key commercial consideration.

Present production methods have several drawbacks. The electrodes are made by spreading a liquid coating composition containing electrode material and a polymeric binder in a solvent system onto one or both sides of a thin foil, which serves as the current collector for the electrodes. Thus, the respective electrodes are made by dispersing mixtures of the respective binders and active particulate materials in a suitable liquid and depositing the wet mixture as a coating layer of controlled thickness on the surface of a current collector foil. The deposited coating layer must then be dried, e.g. in an oven, to force off the solvent, then pressed between calendering rollers to fix the resin-bonded electrode particles to their respective current collector surfaces. This method wastes material as scraps during application of the coating layer, produces regulated emissions during the drying step, and requires space and high energy input for the drying oven. Moreover, using a polymeric binder reduces conductively of the electrode.

In a variation of this basic process, Yu, International Application (PCT) Publication No. WO 2016/082120, which is hereby incorporated herein by reference in its entirety, describes forming a porous layer of electrode particles on a surface using an atmospheric plasma spray device. A non-plasma spray device is then used to spray an aqueous solution of polymeric binder material onto the porous layer. The water evaporates and the polymeric binder bonds the particles together and to the surface.

Deng et al., US Patent Application Publication 2017/0301958, which is hereby incorporated herein by reference in its entirety, describes coating particles of non-metallic lithium-accepting and -releasing materials with smaller particles of a conducting metal via electroless coating or impregnation. For example, an aqueous metal salt solution is combined with a cation complex-forming agent like EDTA. The complex is de-stabilized and chemically reduced to deposit submicron elemental copper particles on an anode material such as lithium titanate. In another example, a metal salt dissolved in ethanol is coated on particles of active electrode material. The solvent is evaporated, then the metal salt-coated particles are annealed in air to form metal oxide particles, then reduced in hydrogen to elemental metal. Once obtained, the active electrode particles bearing smaller particles of metal can be deposited on a substrate by atmospheric plasma spray in making a lithium-ion cell.

Ihde et al., US Patent Application Publication 2012/0261391, which is hereby incorporated herein by reference in its entirety, discloses a method for producing surface-modified particles in atmospheric pressure plasma in which one of the electrodes is a sputter electrode, which sputters the particles due to a discharge between electrodes in a process gas. The surface-modified particles are deposited into polymeric materials to make polymeric coatings containing the metal particles.

There remains a need for a simple and cost-effective method of reliably modifying surfaces of battery electrode material particles with sputtered particles of metal wires for use in manufacturing lithium ion battery electrodes.

### SUMMARY

This need is met by the method now disclosed, in which a metal or metal alloy wire is inserted into an atmospheric plasma stream of a gas to sputter particles of the metal or metal alloy (referred to hereinafter as “the sputtered metal particles”) from the wire, and, inside the same atmospheric plasma stream, the sputtered metal particles contact and adhere with particles of at least one lithium-ion cell active electrode material to produce composite particles of the metal and the active electrode material. The sputtered metal particles and active electrode material particles are believed to adhere because of metal particle surface activation by the atmospheric plasma. Particles of a plurality of different active electrode materials may be used in the method, and the particles of the different active electrode materials may be introduced separately or in admixture to contact the sputtered particles of metal or metal alloy, and more than one type of metal or metal alloy wire may be sputtered. The composite particles are fabricated into an electrode component for a lithium ion cell; the electrode component is combined with other components to make a lithium ion cell; a plurality of the lithium ion cells are combined to make a lithium ion battery.

For embodiments in which the active electrode material is an active anode material which goes through excessive volume changes during lithiation and delithiation, such as silicon-containing or tin-containing anode materials, the active anode material particles are smaller than the sputtered metal particles, typically at least an order of magnitude smaller than the sputtered metal particles. In various embodiments, the sputtered metal particles may have average particle sizes of from about 10 to about 1000 times greater than the average particle size of the active anode material particles, which may be, for example, silicon or silicon oxide particles. For embodiments in which the active electrode material is an active cathode material, the active cathode material particles are typically at least as large as, and may be much larger than, the sputtered metal particles with which they are combined in the atmospheric plasma stream. In various embodiments, the active cathode material particles may have average particle sizes of from about the same size as to about 1000 times greater than the average particle size of the sputtered metal particles. In various embodiments, the sputtered metal particles may be from about 1 nanometer to about 1 micrometer or from about 1 nanometer to about 100 nanometers, and the active cathode material average particle sizes may be from about 1 micrometer to about 20 micrometers or may be from about 5 micrometers to about 10 micrometers.

In various embodiments, a plurality of metal wires, each independently selected from the group consisting of metals and metal alloys, are inserted into and sputtered in an atmospheric plasma to produce particles of the selected metals or metal alloys, at least some of which contact particles of at least one active electrode material inside the same plasma stream and form composite particles in which the metal or metal alloy particles and the particles of the at least one active electrode material adhere together. Particles of a plurality of different active electrode materials may be used, and the particles of the different active electrode materials may be introduced separately or in admixture into the atmospheric plasma stream to contact the sputtered particles of the selected metals or metal alloys.

The composite particles may be applied in a layer on a porous polymeric separator layer, on a solid electrolyte layer, or on a current collector to make an electrode component by atmospheric plasma deposition, and optionally the composite particles may be co-deposited with other particulate material applied by atmospheric plasma deposition from the same or separate plasma nozzles.

An atmospheric plasma (also called an atmospheric pressure plasma or normal pressure plasma) is a cold or non-thermal plasma in which the pressure corresponds approximately to atmospheric pressure. The atmospheric plasma steps is carried out at a temperature less than about 3500° C. or at a temperature less than about 2000° C. In contrast, thermal plasmas typically employ temperatures of 15,000° C. and higher.

The disclosed process for making composite particles for lithium ion battery electrodes provides numerous benefits over previously known processes. In contrast to processes involving electroless plating, impregnation, aqueous solution, and physical vapor deposition, the process now disclosed uses no regulated solvents or solutions requiring evaporation ovens and ventilation. Further, the process can be carried out using metals that would be unsuitable for electroless processes and physical vapor deposition processes. Further, metal and alloy compositions can be better controlled and are less subject to contamination in the presently disclosed process as compared to previous processes. In addition, the size and distribution or concentration of the metal particles and active electrode material particles can be controlled relatively easily, and the process is relatively inexpensive. Other objects and advantages of the practices of this invention will be apparent from the following descriptions of illustrative embodiments.

### BRIEF DESCRIPTION OF THE DRAWINGS

The embodiments can be better understood with reference to the following drawings and description. The components in the figures are not necessarily to scale, emphasis instead being place upon illustrating the principles of the embodiments. The drawings for illustrative purposes only of selected aspects and not all possible implementations, and are not intended to limit the scope of the present disclosure.

FIG. 1 is a schematic illustration of cross-section of an apparatus for carrying out one embodiment of the invention;

FIG. 2A is a cross-section taken along line 2-2 of FIG. 1;

FIG. 2B illustrates an alternative arrangement of sputtering electrodes along line 2-2 of FIG. 1.

FIG. 3 is a schematic illustration of an apparatus having a delivery system and atmospheric plasma nozzle for delivering the composite particles and applying them on a substrate in making an electrode structure.

### DETAILED DESCRIPTION

### Definitions

“A,” “an,” “the,” “at least one,” and “one or more” are used interchangeably to indicate that at least one of the item is present; a plurality of such items may be present unless the context clearly indicates otherwise. All numerical values of parameters (e.g., of quantities or conditions) in this specification, including the appended claims, are to be understood as being modified in all instances by the term “about” whether or not “about” actually appears before the numerical value. “About” indicates that the stated numerical value allows some slight imprecision (with some approach to exactness in the value; approximately or reasonably close to the value; nearly). If the imprecision provided by “about” is not otherwise understood in the art with this ordinary meaning, then “about” as used herein indicates at least variations that may arise from ordinary methods of measuring and using such parameters. In addition, disclosure of ranges includes disclosure of all values and further divided ranges within the entire range.

“Active electrode material” means a lithium intercalation material for either an anode or a cathode of a lithium ion cell or battery.

“Adhered” when used to describe attachment of metal particles surface-energy activated, surface-softened, or surface-melted (together, “surface-activated”) in an atmospheric plasma to other metal particles, active electrode material particles, or a lithium-ion cell substrate means a surface attachment of the metal particles. The metal particles adhere due to the surface energy activation by the atmospheric plasma. The metal particles do not undergo any metallurgical change in the atmospheric plasma.

“Atmospheric plasma” refers to a plasma produced at a temperature up to about 3500° C. and at a pressure at or about at atmospheric pressure. The peak temperature reached by particles in an atmospheric plasma are typically less than about 1200° C.

The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. As used in this specification, the term “or” includes any and all combinations of one or more of the associated listed items.

“Particle size” refers to average particle size as determined by the ISO 13320 test method.

A detailed description of exemplary, non-limiting embodiments, with reference to the figures, follows.

In the disclosed process, a metal wire is subjected to an atmospheric gas plasma stream in a plasma nozzle jet to sputter particles from the metal wire, which are combined with active electrode particles in the atmospheric plasma stream to form composite particles. The metal wire may be of an unalloyed metal or may be an alloy of two or more metals. One metal wire or a plurality of metal wires may be sputtered in the gas plasma. When a plurality of metal wires is used, the metal of each wire may be independently selected from the group consisting of unalloyed metals and metal alloys. In general, the composition of the metal wire or wires that are sputtered in the plasma depends on whether the composite particles will be employed in a cathode layer or in an anode layer. Examples of metals that are suitable to combine with active cathode particles in making composite particles for a cathode layer include, without limitation, Group IIIA, Group IVB, Group VIII, and Group IB metals and alloys of these, such as aluminum, indium, thallium, titanium, zirconium, hafnium, nickel, palladium, platinum, silver, gold, alloys of these, and combinations of wires of these metals and alloys. Examples of metal that are suitable to combine with active anode particles in making composite particles for an anode layer include, without limitation, lithium, Groups IB, VIII, and IVA metals, and alloys of these, such as lithium, copper, silver, gold, nickel, palladium, platinum, tin alloys of these, including LiS and LiSn, and combinations of wires of these metals and alloys.

The metal particles sputtered from the wire in the atmospheric plasma may have an average particle size in the range of nanometers up to a few micrometers. The average particle size selected for the metal particles depends on whether composite particles will be employed in a cathode layer or in an anode layer and on the average particle size of the active electrode material used in making the composite particles. For composite particles for an anode layer, it is beneficial to have metal particles about the same size or larger than the anode active material particles to allow some volume expansion in the anode layer without damaging the anode layer. But metal particles used to make composite particles for a cathode layer may be much smaller that the particle size of the active cathode material.

For anode layer composite particles, the metal particles may be from about 10 nm or from about 30 nm or from about 50 nm or from about 80 nm from about 100 nm or from about 150 nm or from about 200 nm or from about 500 nm or from about 600 nm or from about 700 nm or from about 800 nm or from about 900 nm or from about 1 micrometer up to about 5 micrometers or up to about 3 micrometers or up to about 1 micrometer. The active anode material particles combined with the sputtered metal particles in the atmospheric plasma to form the composite particles may be from about 5 nanometers or from about 10 nanometers or from about 50 nanometers or from about 100 nanometers or from about 200 nanometers or from about 500 nanometers or from about 700 nanometers or from about 900 nanometers up to about 20 micrometers or up to about 15 micrometers or up to about 10 micrometers or up to about 3 micrometers or up to about 1 micrometer. In various embodiments of making composite particles for an anode layer, the metal particles may be from about 1 micrometer to about 5 micrometers or from about 1 micrometer to about 3 micrometers and the active anode material particles may be from about 200 nanometers to about 800 nanometers or from about 250 nanometers to about 750 nanometers or from about 250 nanometers to about 600 nanometers or from about 500 nanometers to about 5 microns or from about 3 microns to about 12 microns.

For cathode layer composite particles, the metal particles may be from about 1 nm or from about 2 nm or from about 5 nm or from about 8 nm from about 10 nm or from about 20 nm or from about 30 nm or from about 40 nm or from about 50 nm or from about 60 nm up to about 1 micrometer or up to about 800 nanometers or up to about 500 nanometers or up to about 400 nanometers or up to about 300 nanometers or up to about 200 nanometers or up to about 100 nanometers. The active cathode material particles combined with the sputtered metal particles to form the composite particles may be from about 1 micrometer or from about 1.5 micrometers or from about 2 micrometers or from about 2.5 micrometers or from about 3 micrometers up to about 20 micrometers or up to about 15 micrometers or up to about 13 micrometers or up to about 12 micrometers or up to about 10 micrometers. In various embodiments of making composite particles for an cathode layer, the metal particles may be from about 1 nanometer to about 1 micrometer or from about 1 nanometer to about 500 nanometers or from about 2 nanometers to about 200 nanometers or from about 2 nanometers to about 100 nanometers and the active cathode material particles may be from about 1 micrometer to about 20 micrometers or from about 2 micrometers to about 15 micrometers or from about 3 micrometers to about 10 micrometers.

A plasma nozzle jet typically has a metallic tubular housing which provides a flow path of suitable length for receiving a flow of a working gas and for enabling the formation of the plasma stream in an electromagnetic field established within the flow path of the tubular housing. The tubular housing typically terminates in a conically tapered outlet nozzle outlet. A stream of a non-oxidizing working gas is introduced at a gas inlet. Suitable plasma process gasses that can be used include, without limitation, nitrogen and noble gases (in particular argon) and mixtures thereof. Noble gases are preferred as the process gas to maintain high conductivity of the metal in the electrode fabricated using the composite material. A linear (pin-like) electrode may be placed at the ceramic tube site along the flow axis of the nozzle at the upstream end of the tubular housing. During plasma generation the electrode is powered by a high frequency generator, for example at a frequency of about 10 to about 50 kHz, and for example to a suitable potential up to a few kilovolts. The metallic housing of the plasma nozzle is grounded, and an electrical discharge can be generated between the axial pin electrode and the housing. When the generator voltage is applied, the frequency of the applied voltage and the dielectric properties of the ceramic tube produce a corona discharge at the stream inlet and the electrode. As a result of the corona discharge, an arc discharge from the electrode tip to the housing is formed. This arc discharge is carried by the turbulent flow of the working gas stream to the outlet of the nozzle. A reactive plasma of the nitrogen (or other working gas) is formed at a relatively low temperature and at atmospheric pressure.

In the method according to the invention, the sputter rate may be controlled by selection of the particular plasma working gas, gas flow rate, distance of the metal wire from the plasma discharging electrodes, the optional bias on the wire (bias potential can be, for example, up to 300 volts), and power used to generate the plasma. The metal wire or metal wires may be located from about 5 to about 100 millimeters or may be from about 20 to about 50 millimeters from the plasma discharging electrodes. In various embodiments, a plurality of metal wires are sputtered in an atmospheric plasma to increase sputter yield. Each of the metal wires may be spaced from the plasma discharge electrodes and from one another so as to control a rate of particle generation from the wire relative to the rate of particle generation from the remaining wires.

Active electrode particles are introduced into the plasma stream so as to come into contact with the sputtered metal or metal alloy particles. Nonlimiting examples of suitable active anode materials include silicon-containing materials such as elemental silicon, silicon alloys, SiOₓ (e.g., SiO—SiO₂ composite), silicon oxide-carbon composites, silicon-carbon composites; lithium alloys such as Li—Si alloys, Li—Sn alloys, and Li—Sb alloys; lithium metal oxides such as lithium titanate; other metal oxides (e.g., Fe₂O₃, ZnO, ZnFe₂O₄); carbon-containing materials such as graphite (both synthetic graphite and natural graphite), graphene, mesocarbon, doped carbon, hard carbon, soft carbon, fullerenes; metallic lithium, niobium pentoxide, tin alloys, titanium dioxide, and tin dioxide; and combinations of these. A suitable active anode material can be formed in the atmospheric plasma from a vaporized siloxane compound such as hexamethyldisiloxane (HMDSO) or a tetraalkylsiloxane like tetraethylsiloxane (TESO), which may optionally further comprise an alkane gas such as methane, ethane or propane to provide carbon. Similarly, a lithiated (lithium-doped) active anode material, e.g. an SiOₓ—Li composite or SiOₓ—C—Li composite, may be formed in the plasma stream by mixing an organic lithium precursor vapor with a precursor vapor for SiOₓ (such as a tetraalkylsiloxane like tetraethylsiloxane or a hexaalkyldisiloxane such as hexamethyldisiloxane) and optionally including a secondary carbon source (such as an alkane like methane, ethane, or propane). Examples of organic lithium precursors are lithium acetate, lithium bis(n-propyldimethylsilyl)amide, and lithium bis(trimethylsilyl)amide.

Nonlimiting examples of suitable active cathode materials include lithium metal oxides, layered oxides, spinels, olivine compounds, silicate compounds, HE-NCM, and combinations of these. Examples include lithium manganese oxide (LMO), lithium nickel oxide, lithium cobalt oxide (LCO), lithium nickel cobalt aluminum oxide (NCA), lithium manganese nickel cobalt oxide (NMC), lithium iron phosphate (LFP), Li-manganese spinel (LiMn₂O₄), Li manganese nickel oxide (LMNO), lithium-rich transition-metal oxides such as (Li₂MnO₃)ₓ(LiMO₂)₁₋ₓ, layered oxides, spinels, olivine compounds, other lithium complementary metal oxides or phosphates, and combinations of these. Examples of olivine compounds include lithium phosphates of empirical formula LiXPO₄ with X=Mn, Fe, Co or Ni, or combinations thereof. Examples of lithium metal oxide, spinel compounds, and layered oxides include lithium manganate, preferably, LiMn₂O₄, lithium cobaltate, preferably, LiCoO₂, lithium nickelate, preferably, LiNiO₂, or mixtures of two or more of these oxides, or the mixed oxides thereof.

The active electrode material may also include mixtures of active cathode materials or mixtures of active anode materials. In one embodiment, particles selected for increasing electrical conductivity, for example particles of carbon-containing material such as conductive carbon black, graphite, carbide-derived carbon, graphene, graphene oxide, carbon nanotubes and combinations thereof, are also introduced into the plasma stream to be incorporated into composite particles.

In various embodiments, the active anode material particles are from about 5% to about 75% of the total volume, preferably from about 20% to about 70% of the total volume, and more preferably from about 20% to about 60% or from about 40% to about 70% or from about 40% to about 60% of the total volume of the anode composite particles produced in the atmospheric plasma by combination of the metal particles and active anode material particles. In various embodiments, the active cathode material particles occupy from about 70% to about 95% of the total volume, preferably from about 75% to about 92% of the total volume, and more preferably from about 80% to about 90% or from about 85% to about 90% or from about 87% to about 89% of the total volume of the cathode composite particles produced in the atmospheric plasma by combination of the metal particles and active cathode material particles.

In another embodiment, a stream of an oxidizing working gas, such as oxygen or air, is introduced at a gas inlet to form an oxidizing atmospheric plasma. In this embodiment, the sputtered metal or metal alloy particles will form at least a surface layer of a metal oxide. This embodiment may be used to produce a composite particle containing a stabilizing, lithium ion conductive metal oxide member. For example, aluminum wire may be sputtered in an oxidizing working gas in making a composite particle for a cathode, in which the composite particle contains a member with an aluminum oxide surface. As another example, a zirconium or zinc wire may be sputtered in an oxidizing working gas in making a composite particle for an anode, in which the composite particle contains a member with a zirconium or zinc oxide surface.

It may be that some of the metal particles and active material particles may not form composite particles, but such uncombined particles can later be incorporated into the electrode layer during atmospheric plasma deposition of the combined particles and any uncombined particles. Forming an electrode layer on a lithium ion cell substrate includes a step of introducing collected composite particles (and any metal particles and active material particles that were not combined) into an atmospheric plasma deposition device and depositing them in an electrode layer onto the substrate to make an electrode component for a lithium ion battery.

The composite particles may be collected, for example in a cyclone under an inert atmosphere, or may be directed into a second plasma nozzle to be deposited onto a substrate in a plasma deposition process to form an electrode component. The substrate receiving the electrode layer of composite particles may be a metal foil current collector, a porous separator layer, or a solid electrolyte layer.

In general, metal foil current collectors are coated on both of their major surfaces with the composite electrode materials. The thicknesses of the electrode layers may be varied for the purpose of managing the capacity of the layers to accept and release lithium ions.

In many battery constructions, the separator material is a porous layer of a polyolefin, such as polyethylene (PE), polypropylene (PP), porous polyvinyl chloride film, non-woven, cellulose/acryl fibers, cellulose/polyester fibers, or glass fibers. Often the thermoplastic material comprises inter-bonded, randomly oriented fibers of PE or PP. The fiber surfaces of the separator may be coated with particles of alumina, or other insulator material, to enhance the electrical resistance of the separator, while retaining the porosity of the separator layer for infiltration with liquid electrolyte and transport of lithium ions between the cell electrodes. A separator film may have a thickness of 15 micrometers to 50 micrometers. Such separators may be used in combinations, such as with a three-layer coated separator of a porous polyethylene film sandwiched between outer porous polypropylene films. The separator layer is used to prevent direct electrical contact between the facing negative and positive electrode material layers and is shaped and sized to serve this function. In the assembly of the cell, the facing major faces of the electrode material layers are pressed against the major area faces of the separator membrane. A liquid electrolyte is typically injected into the pores of the separator and electrode material layers. In an assembled lithium ion electrochemical cell, a porous separator will have an anode layer on one side and a cathode layer on its other side.

Other battery constructions use a solid electrolyte layer of a lithium ion conductive polymer electrolyte film or a ceramic electrolyte.

A battery cell is formed from a number of positive and negative charged electrodes depending on the total capacity requirement. Each electrode is formed of porous layers of active anode material particles for a lithium ion cell, active cathode material particles, or combinations of capacitor electrode materials with anode or cathode material particles, bonded to each side of a suitable current collector foil. The current collector foils are typically rectangular in shape with height and width dimensions suitable for assembly by stacking or winding into a unitary package of one or more electrochemical cells. If the finished electrochemical cell is to be formed of a stacking of two or more pairs of electrodes (and their interposed separators) the current collector foils with their coatings of electrode materials may be rectangle as is practiced in the formation of lithium batteries. If the finished electrochemical cell is to be formed by winding of the cell units and separators, the foils may be quite long as is practiced in the formation of lithium batteries.

The invention is further explained now with reference to the figures.

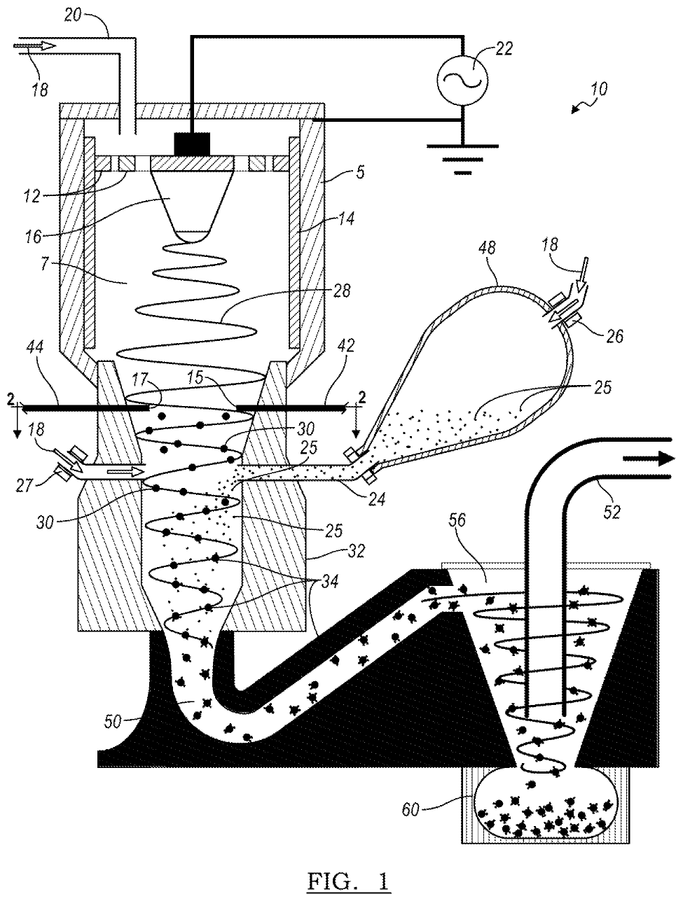

FIG. 1 is a cross-sectional view of a plasma nozzle and particle collection device 10. The plasma nozzle has an electrically conductive housing 5, which preferably has an elongated, in particular tubular, shape, and an electrically conductive nozzle head 32. The housing 5 and the nozzle head 32 form a nozzle channel 7 through which a process gas 18 flows. Inner electrode 16 is arranged in the nozzle channel and connected to high voltage power supply 22. Advanceable metal wires 42, 44 are situated in the plasma nozzle channel 7. The housing 5 is grounded and lined with a ceramic sleeve 14. The process gas 18 is introduced into the nozzle channel 7 via a line 20, so that it flows through the channel in a swirling manner. The swirling or spiraling flow of the process gas is illustrated by the spiral line 28. Such a flow of the process gas can be achieved by means of a swirler 12, shown as a plate with holes.

Owing to the high voltage, a discharge, in particular an arc discharge, is ignited between the electrode 16 and nozzle head 32 to produce a plasma. The discharge causes particles 30 to be sputtered from the tips 15, 17 of the metal wires 42, 44 and are transported with the swirling gas flow 28.

Active electrode material particles 25 are supplied from particle feeder 48 via inlet 24 downstream of metal wires 42, 44. The transport of the active electrode material particles 25 through the line 24 is achieved with the aid of process gas 18 entering through inlet 26, and further process gas introduced through opposite inlet 27 aids in contacting active electrode material particles 25 with metal particles 30. At least some of the active electrode material particles 25 contact metal particles 30 while metal particles 30 have a surface activated by the plasma and attach to form composite particles 34. It should be understood that, while active electrode material particles 25 are shown in this embodiment as smaller than metal particles 30, in other embodiments the active electrode materials may be about the same size as or larger than the metal particles.

Composite particles 34 are swept by the process gas through passage 50 into cyclone 56 and collected in area 60. The process gas is exhausted through outlet 52.

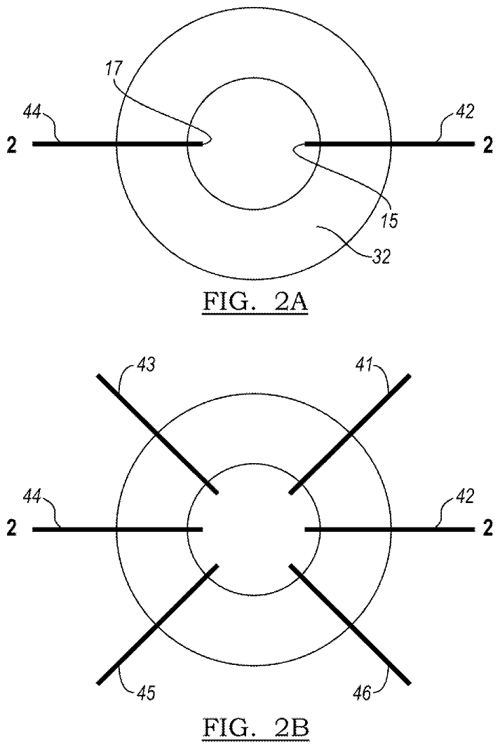

FIG. 2A is a cross-section at line 2-2 showing an arrangement of metal wires 42, 44 opposite one another with tips 15, 17 inside the plasma nozzle head 32. FIG. 2B shows an alternative arrangement including additional metal wires 41, 42, 43, 44, 45, and 46 spaced around the circumference of the plasma nozzle head 32 acting as additional sputtering sources for producing metal particles 30.

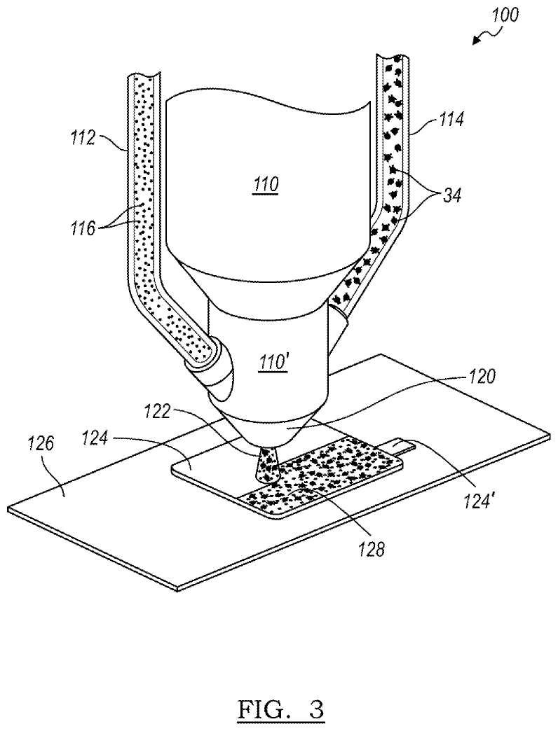

Composite particles 34 are fabricated into an electrode component for a lithium ion cell. FIG. 3 shows an atmospheric plasma deposition apparatus 100 with an upstream round flow chamber 110 for introducing and conducting a flowing stream of suitable working gas, such as nitrogen or an inert gas such as helium or argon. Flow chamber 110 is tapered inwardly to smaller round flow chamber 110′. Composite particles 34 are introduced through supply tube 114 (partially broken away to show the flow of composite particles 34) and an optional second active electrode material 116 is shown in this example being introduced through supply tube 112 (partially broken away to show the flow of active electrode material 116) into the working gas stream in a main chamber and then carried into a plasma nozzle 120 in which the working gas is converted to a plasma stream at atmospheric pressure. As the composite particles 34 enter the plasma stream, they are dispersed and their metal portions are activated by the plasma as they are mixed with second active electrode material particles 116. The activated metal surfaces cause the composite particles 34 and optional second active electrode material 116 to adhere to one another and to substrate 124 during deposition. The second active electrode material particles 116 may also become entrapped in voids of a porous network of composite particles 34 formed on substrate 124. While not shown, unattached particles of the first active anode material 25 may be admixed with composite particles 34 and introduced along with composite particles 34 into the plasma stream. Like the second active electrode material particles 116, the first active anode material 25 may adhere to the composite particles 34 activated by the atmospheric plasma or become trapped in the porous network deposited onto substrate 124.

The stream 122 of nitrogen-based plasma containing and carrying suspended electrode material particles is progressively directed by the nozzle against the surface of a substrate 124, which may be, for example, a current collector foil for a lithium-ion cell. The substrate foil is supported on a suitable working surface 126 for the atmospheric plasma deposition process. The deposition substrate for the atmospheric plasma deposition is illustrated as an individual current collector foil 124 with its un-coated connector tab 124′. But it is to be understood that the substrate for the atmospheric plasma deposition may be of any size and shape for economic use and application of the plasma. It is also to be understood that suitable fixtures may be required to secure the substrate in place and/or a mask may be required to define the coated area or areas. And further, for example, specified smaller working electrode members may later be cut from a larger initially coated substrate. The nozzle is moved in a suitable path and at a suitable rate such that the electrode layer 128 is a desired thickness on the surface of the current collector foil substrate 124. The plasma nozzle may be carried on a robot arm and the control of plasma generation and the movement of the robot arm be managed under control of a programmed computer. In other embodiments of the invention, the substrate is moved while the plasma is stationary.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

1. A method of making an electrode material for a lithium-ion electrochemical cell, comprising:
in an atmospheric plasma, sputtering a wire of metal or metal alloy to produce activated particles of metal or metal alloy and
contacting the activated particles of the metal or metal alloy with particles of a lithium-ion cell active electrode material to produce composite particles in which particles of the lithium-ion cell active electrode material are adhered to particles of the metal or metal alloy.

2. A method according to claim 1, further including collecting the composite particles in a cyclone.

3. A method according to claim 1, wherein the metal or metal alloy is selected from the group consisting of aluminum, indium, thallium, titanium, zirconium, hafnium, nickel, palladium, platinum, silver, gold, and alloys thereof and the lithium-ion cell active electrode material is an active cathode material.

4. A method according to claim 1, wherein the metal or metal alloy is selected from the group consisting of lithium, copper, tin, silver, gold, nickel, palladium, platinum, and alloys thereof and the lithium-ion cell active electrode material is an active anode material.

5. A method according to claim 1, wherein a plurality of wires, each independently selected from the group consisting of metals and metal alloys, are sputtered in the atmospheric plasma to produce the activated particles of metal or metal alloy.

6. A method according to claim 1, wherein the atmospheric plasma is non-oxidizing.

7. A method according to claim 1, wherein the atmospheric plasma is oxidizing.

8. Composite particles made by a method according to claim 1.

9. A method of making an electrode component for a lithium-ion electrochemical cell, comprising using atmospheric plasma deposition to deposit composite particles according to claim 8 into an electrode layer on a lithium-ion electrochemical cell substrate.

10. A method according to claim 9, wherein, particles of a second lithium-ion cell active electrode material are co-deposited with the composite particles.

11. A method according to claim 10, wherein the second lithium-ion cell active electrode material is a carbonaceous material.

12. An electrode component made by a method according to claim 9.

13. A lithium ion electrochemical cell comprising the electrode component according to claim 12.

14. A lithium ion battery comprising the lithium ion electrochemical cell according to claim 13.
